(19) United States
(12) Patent Application Publication
(10) Pub. No.: US 2006/0177565 A1
(43) Pub. Date: Aug. 10, 2006

(54) Paint circulation system

(76) Inventors: Shubho Bhattacharya, Dublin, OH (US); Jianhua Xu, Columbus, OH (US); Kurt W. Koelling, Powell, OH (US)

Correspondence Address: DINSMORE & SHOHL, LLP, 1900 CHEMED CENTER, 255 EAST FIFTH STREET, CINCINNATI, OH, 45202, US

(21) Appl. No.: 11/052,564

(22) Filed: Feb. 7, 2005

(51) Int. Cl. C23C 16/52; B05C 11/00

(52) U.S. Cl. 427/8; 118/683

(57) ABSTRACT

Circulation systems and methods for dispensing paint, more particularly those systems and methods which are configured to provide one or more paints to automotive paint applications are provided.

### TECHNICAL FIELD

The present invention relates to a paint circulation and dispensing system and method, and more particularly to a closed loop system and method capable of providing one or more paints for automotive paint applications.

### BACKGROUND OF THE INVENTION

Sophisticated painting systems are commonly used in automotive manufacturing facilities to provide the final paint finish on vehicles. Conventional large painting systems generally include several paint booths each equipped with multiple paint loops, with each loop consisting of one color. A paint loop generally includes a tank, a pump, piping, and multiple paint distributors (e.g., spray guns or robots). In order to provide the necessary pressure for the paint distributors to properly operate and to avoid particles in the paint from settling, the pump is continuously operated.

Current paint system designs are generally operated as batch processes, where only one color is applied to a vehicle at one time. However, all of the other loops (e.g., colors) in the system must remain at elevated pressures in order to maintain paint circulation while not in use. Such process designs lead to inefficiency, wasted pumping energy and paint degradation, particularly for metallic paints. However, the idle loops need to be operated to prevent particles in the paint from settling, to provide proper flow speed and pressures, and to provide continuous steady state operation of all loops within the paint system.

Accordingly, there is a need for a paint circulation system which maintains an effective amount of pressure and/or flow rate to the operating and idling loops, to provide a steady state operation within the paint circulation system.

### SUMMARY OF THE INVENTION

Accordingly, it is an aspect of the present invention to provide a paint circulation dispensing system and a method for using the same.

To achieve the foregoing and other aspects, and in accordance with the purposes of the present invention defined herein, a circulation system for dispensing paint is provided. In an exemplary embodiment, this circulation system generally includes a paint loop having an operating loop and at least one idling loop. The system also generally includes, a pump, a transmitter, a controller, transducers, and regulators. The pump is configured to pressurize the paint loop. The operating loop is defined by a first set of parameters. The transmitter is located in the paint loop and is configured to measure the first set of parameters and transmit the input data signal associated with the first set of parameters. The controller in the circulation system includes an input configured to receive the input data signal and outputs configured to transmit output data signals. The output data signals include instructions to maintain the first set of parameters in the operating loop within a predetermined range. The transducers are located in the circulation system. The transducer associated with the idling loop, having received one of the output data signals, instructs a regulator in the idling loop to maintain a second set of parameters in the idling loop.

In another exemplary embodiment of the present invention, a method of controlling a paint circulation system is provided. The method includes providing a paint loop having an operating loop and at least one idling loop with paint circulating in each loop. A first set of parameters associated with the paint in the operating loop is measured. A pump in the operating loop is instructed to maintain the first set of parameters within a predetermined range. A regulator and the pump in the idling loop is instructed to maintain a second set of parameters within the idling loop.

The circulation system for dispensing paint and methods of operating the same as described herein are advantageous for providing a closed loop circulation system capable of providing one or more paints for automotive paint applications. Additional aspects, advantages, and novel features of the invention will be set forth in the description that follows, and/or will become apparent to those skilled in the art upon examination of the following, and/or may be learned with the practice of the invention. The aspects and advantages of the invention may be realized and obtained by means of the instrumentalities and combinations particularly pointed out in the appended claims.

### BRIEF DESCRIPTION OF THE DRAWINGS

While the specification concludes with the claims particularly pointing out and distinctly claiming the present invention, it is believed that the same will be better understood from the following description taken in conjunction with the accompanying drawings in which:

FIG. 1 depicts a schematic layout illustrating one exemplary embodiment of the circulation system for dispensing paint having a paint loop where the operating loop and idling loop are in a parallel arrangement.

FIG. 2 illustrates a schematic layout of another exemplary embodiment of a circulation system for dispensing paint having a paint loop where the operating loop and idling loop are in a series arrangement.

### DETAILED DESCRIPTION OF THE EXEMPLARY EMBODIMENTS

The present invention provides particular advantages previously unavailable in industries where circulation systems for dispensing paints are applied, particularly in the automotive industry. Current paint circulation system designs require a pressure transmitter to be used downstream of a pump in order to sense pressure fluctuations in the operating loop as spray applicators or distributors are turned on or off. The pressure transmitter sends a signal to the programmable logic controller (PLC) which in turn controls the variable frequency drive (VFD) motor on the pump to change the pump speed and maintain a certain discharge pressure. Moreover, under such systems it is known that some paints do not remain stable with respect to some of their property characteristics, over time, particularly when they are subjected to shear forces while being pumped throughout the circulation system.

In contrast to prior systems, the present invention provides a paint circulation system with a transducer positioned upstream from the tank. The transducer receives a pressure signal from the PLC and instructs the opening of a regulator as the pump maintains the required pressure and/or flow rate within the circulation system. This system provides a mechanism to effectively reduce pumping costs, while simultaneously preventing detrimental effects to the property characteristics of the paint. Thus, because adequate flow speed is maintained in both the operating loop and the idling loop such that no settling of material occurs in either loop, there is a reduction in the amount of cleaning or flushing of the paint loop that would be required in conventional circulation systems.

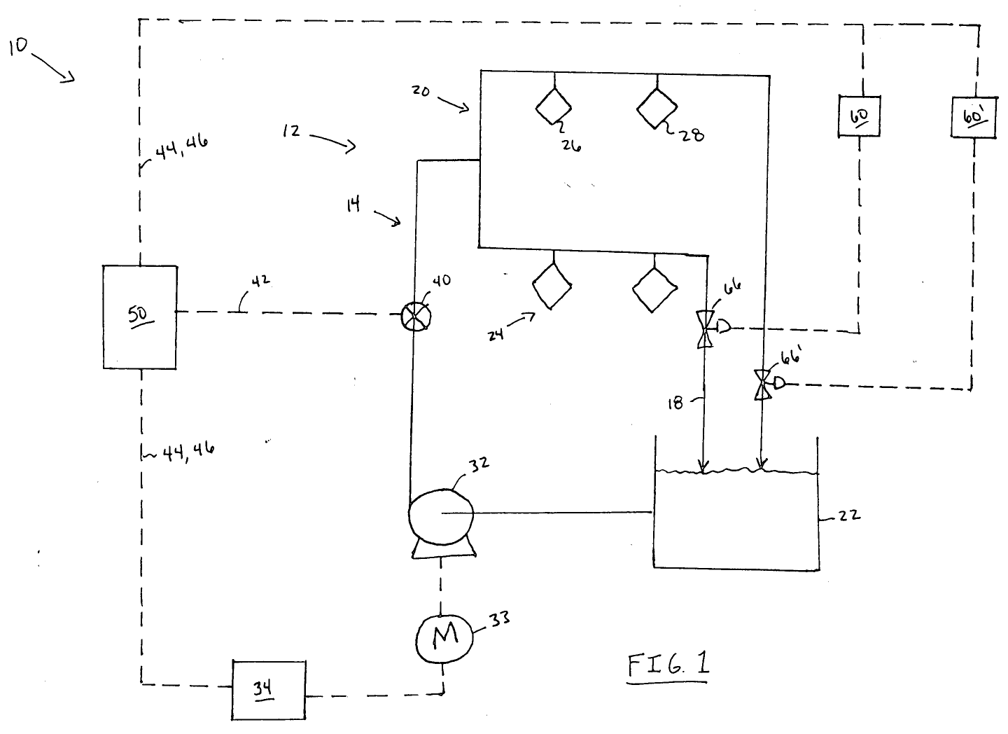

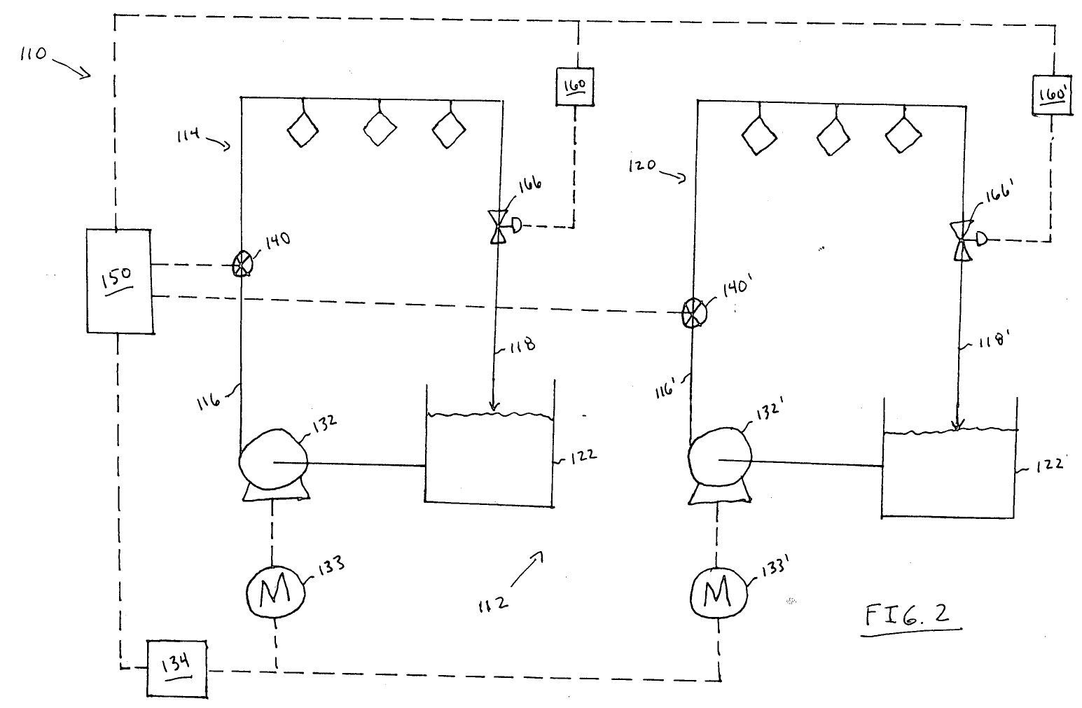

The embodiments of the present invention and its operation are herein described in detail in connection with the views and examples of FIGS. 1 and 2. FIG. 1 depicts one exemplary embodiment of the circulation system for dispensing paint such that the pressure provided by the pump in the operating loop and the idling loop are controlled, thus, providing adequate pressure to be maintained throughout the circulation system, thereby significantly reducing overall energy costs while maintaining paint characteristics and quality. It will be appreciated that for purposes of explanation, one of the circulating paint loops is termed the operating loop while the other is termed the idling loop. However, both loops have substantially the same structural and operational characteristics. When one desires to dispense a different paint, the operating loop becomes an idling loop, and one of the idling loops is activated to become the current operating loop. FIG. 1 shows the circulation system having an operating loop and idling loop in a parallel arrangement, while FIG. 2 illustrates an operating loop and idling loop in a series arrangement.

FIG. 1 depicts a schematic layout of one exemplary embodiment of the circulation system 10 for dispensing paint. The circulation system 10 generally includes a paint loop 12 having an operating loop 14 and at least one idling loop 20, where the operating loop 14 and idling loop 20 have a parallel arrangement with respect to each other. As shown in FIG. 1, the paint loop 12 is selectively connected to a holding facility (e.g., a source tank 22) which maintains the paint which will be pumped through the operating loop 14. The operating loop 14 is where the paint is actively transported through the paint loop 12 as the circulation system 10 is in operation. The idling loop 20 includes the loop not currently having paint dispensed from it. The return line 18 includes paint which has been cycled through the operating loop 14 and which is returned to source tank 22 or another holding facility. Thus, excess paint having passed through the entire operating loop 14 that has been returned to the source tank 22 or holding facility can be recycled if reusable, or otherwise disposed of properly.

In another exemplary embodiment, the paint loop may include a plurality of idling loops such that additional paints can flow within the circulation system for application to a designated material or part when the idling loops switch to become the current operating loop.

Paint as understood in the application is used broadly to include water and solvent borne paints, particularly both metallic and non-metallic paints, all of which may pass through the circulation system 10 either via the operating loop 14 or through the idling loop 20. In addition, those skilled in the art will appreciate that other paint materials may also be included in the circulation system 10, such as base coats and primers applied prior to the paint coat, and finishers and clear coats, which can be applied subsequent to the paint applications. The paint materials can contain binders or binder mixtures, which are present in solution in suitable solvent mixtures, as well as pigment mixture and extender mixtures.

The paint loop 12, itself, is constructed of material capable of containing the paint. For example, it can be comprised of metal or plastic components, such that the paint does not substantially react physically or chemically with the material in any way to substantially affect the paint's composition or quality. Stainless steel is commonly used for various piping and fittings that make up the paint loop 12.

In order to pressurize the paint loop 12, a pump 32 in the paint loop 12 is configured to provide the mechanism by which to force paint from the source tank 22, through the operating loop 14, to distributors 24, and finally back to either the source tank 22 or another holding facility. The pump 32 is coupled with a respective motor 33 (e.g., a variable frequency drive motor) with an associated motor control 34 allowing the pump 32 to change or alter the amount of pressure it exerts on the paint loop 12. In an exemplary embodiment, the source tank 22 can be pneumatically pressurized through a source of air, which is supplied through a regulator, check valve or shutoff valve to the source tank 22 through an air line. The paint is supplied from the source tank 22 at a pressure ranging from about 100 psi to about 150 psi. When the paint is passed to a distributor 24 and released, a pressure drop in the the operating loop 14 occurs. When this happens, the pump 32 is signaled to increase the pressure in the operating loop 14 to maintain the flow of paint within the upper and lower limits of a predetermined range. The pump 32 may include a direct current motor drive system. Such a motor control includes a microprocessor whereby the motor control may be adjusted to maintain the paint in operating loop 14 to have a set of parameters which remain within the predetermined range. The motor speed and current during pumping can be monitored using suitable sensors (not shown) which provide an indication of the pressure and/or flow rate within the paint loop 12. In another exemplary embodiment, the circulation system can include more than one pump to pressurize the circulation system (e.g., multiple pumps in either the operating loop or idling loop).

In order to dispense the paint to designated parts, distributors 24 are used to apply the paint to such parts. The distributors 24 exist along both the operating loop 14 and the idling loop 20. These distributors 24 may include spray guns 26 or robots 28 which expel the paint from the paint loop 12. Thus, distributors 24 can be either automated or manual in nature. In many applications today both robots and individuals apply paint to the respective parts for automobiles. For example, in the automotive industry body parts for various vehicles are generally painted both automatically with robots 28 and manually with spray guns 26, in order to ensure substantially complete coverage of the part.

The properties of the paint as it flows through the circulation system 10 includes a first set of parameters which defines conditions in the operating loop 14 and a second set of parameters defining the conditions in the idling loop 20. The first set of parameters can include one or more of viscosity, flow rate, temperature or pressure values for the paint in the operating loop 14. These parameters influence the property characteristics of the paint as it flows through the operating loop 14. The second set of parameters comprises one or more of viscosity, flow rate, temperature or pressure values for the paint in the idling loop 20, thus also influencing the property characteristics of the paint in the idling loop 20.

A transmitter 40 is configured to measure the first set of parameters associated with the paint and is located in the paint loop 12. The transmitter 40 sends an input data signal 42 associated with the first set of parameters which includes the values of the first set of parameters. As previously noted, these values can include the particular viscosity, flow rate, temperature and/or pressure values associated with the paint as it travels through the operating loop 14. The transmitter 40 can include sensors (e.g., a flow meter). The sensors can measure the property characteristics of the paint as it flows through the paint loop 12 and communicate this information to a controller 50.

The controller 50 oversees the circulation system 10 and has an input, configured to receive the input data signal 42, and at least one output, configured to transmit output data signals. The output data signals include instructions to maintain the first set of parameters associated with the paint while it is in the operating loop 14 so that the first set of parameters stay within a predetermined range. In one exemplary embodiment, the output data signals include first 44 and second 46 output data signals. The first output data signal 44 includes one or more of viscosity, flow rate, temperature or pressure values for the paint. In one exemplary embodiment, the first output data signal 44 is speed, where the speed can be considered either high or low, for example, this instructs the pump 32 to maintain a given pressure within the operating loop 14. The predetermined range includes an upper and a lower limit for the values defined in the first set of parameters. This predetermined range can be set by the user or operator of the circulation system 10 in order to maintain the characteristics and/or quality of the paint within a desired specification. For example, if any changes in the pressure or flow rate occurred in the circulation system 10, such alterations could be regulated and controlled, thus, returning the paint to within its desired specification having a first set of parameters within its predetermined ranges. In another exemplary embodiment, the controller includes a plurality of inputs and outputs, allowing for additional input or output data signals to be sent or generated. In one particular embodiment, the controller is a process logic control (PLC). In another exemplary embodiment, the controller may also include a computer having associated software (not shown), wherein the computer provides the user or operator the ability to make changes to the designated programming, thus introducing more flexibility into the system. Moreover, the computer can be accessed remotely through a network which allows monitoring and control of the circulation system from various locations.

Transducers 60,60′ communicate with the controller 50 and regulators 66,66′ located in the operating loop 14 and idling loop 20 respectively. The transducers 60,60′ are configured to receive the output data signals. The transducers 60,60′ use the output data signals to instruct regulators 66,66′ to maintain a first set of parameters in operating loop 14 and a second set of parameters in idling loop 20. The regulators 66,66′ are operated in tandem with the pump 32 which pressurizes the circulation system 10, thus providing advantages and benefits not previously known in automotive and industrial paint applications. In one exemplary embodiment, the transducers 60,60′ are electro-pneumatic transducers. The transducers 60,60′ communicate with the regulators 66,66′ respectively by pilot air connections (not shown). The transducers 60,60′ connect to the pilot air connections to operably command regulators 66,66′ to open or close such that the paint in the operating loop 14 and in the idling loop 20 is maintained at values associated with the correct set of parameters. For example, during substantially steady state operations, the pressure in the operating loop 14 is maintained at a value much higher than that maintained in the idling loop 20, thus reducing energy costs throughout the circulation system 10 without compromising the quality of the paint. The regulators 66,66′ in one exemplary embodiment are back-pressure regulators.

FIG. 2 illustrates an exemplary embodiment of a circulation system 110 where a paint loop 112 has a series arrangement with respect to the operating loop 114 and the idling loop 120, where each loop has its own pump 132,132′ and transmitter 140,140′, respectively. The operating loop 114 having a supply line 116 draws paint from a source tank 122 via the pump 132′ to send paint through the operating loop 114. The pump 132 in the idling loop 120 provides the necessary pressure to transfer another paint through the idling loop 120 which accesses its supply of paint from another source tank 122′. The pumps 132,132′ are each coupled and driven by motors 133,133′ having an associated motor control 134. Each loop 114, 120 contains a transmitter 140,140′ in the supply lines 116,116′ which transmit an input data signal to a controller 150 in the circulation system 110 to provide the conditions in the operating loop 114 defined by a first set of parameters. In order to maintain the conditions in the operating lcop 114 but reduce energy in the idling loop 120, transducers 160,160′ in the return lines 118,118′ of the loops 114,120 along with the pumps 132,132′ interact with the controller 150 to receive instructions in the form of output data signals to operate regulators 166,166′ to maintain the first set of parameters in the operating loop 114 within a predetermined range and define the idling loop 120 by a second set of parameters.

This series arrangement provides additional flexibility to the parallel arrangement by having the idling loop 120 independently drawing its paint from another source tank 122′. This series arrangement eliminates the need for any flushing or changing of the paint loop 112 where a color change or change in paint type occurs when the current idling loop 120 becomes the next operating loop 114 in the process. Moreover, this series arrangement does generally provide the same benefits as the parallel arrangement shown in FIG. 1. In addition, it is important to appreciate that the parallel and series arrangements can be combined so that another exemplary embodiment could include a paint loop having loops arranged in both parallel and series with respect to each other when multiple idling loops are involved.

In another exemplary embodiment, the circulation system further comprises a paint booth (not shown). The paint booth generally includes a housing in which parts can pass or are maintained while the paint is applied to the particular parts or components as they pass through a housing. Distributors are usually connected by supply ducts, such as hoses, to the paint loop in the paint booths. In an exemplary embodiment, paint is applied to parts of a vehicle while they travel along an assembly line where a plurality of robots can be positioned along opposite sides of the assembly line as it passes through the paint booth. In addition, manual spray guns may be used to paint some portions of the vehicle, particularly those which pose difficult-to-reach locations. As previously mentioned, the circulation system may include more than one paint, such that one paint may exist in the operating loop while another one is maintained in one of the idling loops. Thus, multiple paints can be utilized within a single paint booth. However, the system can also be arranged so that multiple booths can be used to provide locations for additional paints to be applied.

An exemplary method for controlling the paint circulation system includes providing a paint loop having an operating loop and at least one idling loop with paint circulation in each respective loop. A first set of parameters is measured associated with the paint in the operating loop.

An input data signal having the first set of parameters is transmitted by transmitter to the controller. When the input data signal is received, controller generates output data signals. The output data signals are transmitted to a pump in the paint loop and transducers (with instruct first and second regulators) in both the operating and idling loops. The pump and a first regulator are instructed with one output data signal to maintain the first set of parameters within a predetermined range. Another output data signal is received by the transducer in the idlingloop. Using this output data signal, the pump and a second regulator are instructed to maintain a second set of parameters within the idling loop.

The method provides for a color changeover in the system without detrimentally affecting the characteristics of paint circulating in the system. When one colored paint is spraying, the regulators on the idling loops are opened and the pumping speed is reduced. When a new batch of parts enters the paint booth and a color change over is required, the controller receives the necessary information, increases the pumping speed, and closes the regulator(s) to achieve the required operating condition. The previous operating loop then becomes the idling loop and the pressure is lowered. The pressures maintained in the idling loops are relatively low, but the flow speed is maintained, thus avoiding particle settling, reducing pumping energy and lowering the shear force on the paint.

The foregoing description of exemplary embodiment examples of the invention have been presented for purposes of illustration and description. It is not intended to be exhaustive or limit the invention in the forms described. Numerous modifications are possible in light of the above teachings. Some of these modifications have been discussed, and others will be understood by those skilled in the art. The embodiments have been chosen and described in order to best illustrate the principles of the invention and various embodiments as they are suited in their particular use contemplated. It is hereby intended that the scope in the invention be defined by the claims appended hereto.

What is claimed is:

1. A circulation system for dispensing paint, the circulation system comprising:
a paint loop comprising an operating loop and at least one idling loop;
at least one pump configured to pressurize the paint loop, wherein the operating loop is defined by a first set of parameters;
at least one transmitter located in the paint loop configured to measure the first set of parameters defining the operating loop and transmit an input data signal associated with the first set of parameters;
a controller in the circulation system having an input configured to receive the input data signal and outputs configured to transmit output data signals, the output data signals including instructions to maintain the first set of parameters in the operating loop within a predetermined range;
at least two transducers located in the circulation system and configured to receive the output data signals, wherein one of the transducers is associated with the idling loop; and
at least two regulators, wherein one of the regulators is located in the idling loop, and wherein the transducer associated with the idling loop having received one of the output data signals from the controller instructs the regulator located in the idling loop to maintain a second set of parameters defining the idling loop.

2. The circulation system as recited in claim 1, wherein the circulation system comprises a plurality of idling loops.

3. The circulation system as recited in claim 1, wherein the operating loop and the idling loop comprise distributors.

4. The circulation system as recited in claim 3, wherein the distributors are spray guns.

5. The circulation system as recited in claim 3, wherein the distributors are robots.

6. The circulation system as recited in claim 1, wherein the paint loop is constructed of conduit material capable of containing the paint.

7. The circulation system as recited in claim 1, wherein the paint is a water or solvent borne paint.

8. The circulation system as recited in claim 7, wherein the paint is a metallic paint.

9. The circulation system as recited in claim 7, wherein the paint is a nonmetallic paint.

10. The circulation system as recited in claim 1, wherein the circulation system comprises a plurality of pumps.

11. The circulation system as recited in claim 1, wherein the transmitter comprises a sensor to measure the first set of parameters.

12. The circulation system as recited in claim 1, wherein the first set of parameters comprises one or more of the viscosity, flow rate, temperature or pressure values for the paint in the operating loop.

13. The circulation system as recited in claim 12, wherein the input data signal comprises the values defined in the first set of parameters.

14. The circulation system as recited in claim 12, wherein the predetermined range includes an upper and lower limit for the values defined in the first set of parameters.

15. The circulation system as recited in claim 1, wherein one of the output data signals comprise one or more of viscosity, flow rate, temperature or pressure values for the paint in the operating loop.

16. The circulation system as recited in claim 1, wherein the controller is a process logic controller.

17. The circulation system as recited in claim 1, wherein the transducer is an electro-pneumatic transducer.

18. The circulation system as recited in claim 1, wherein the second set of parameters comprises one or more of viscosity, flow rate, temperature or pressure values for the paint in the idling loop.

19. The circulation system as recited in claim 18, wherein one of the output data signal includes the values of the second set of parameters.

20. The circulation system as recited in claim 1, wherein the transducer communicates with the regulator by a pilot air connection.

21. The circulation system as recited in claim 1, wherein the regulator is a back pressure regulator.

22. The circulation system as recited in claim 1, where in the circulation system further comprises a spray booth.

23. The circulation system as recited in claim 1, wherein the operating loop and idling loop comprise different paints.

24. The circulation system as recited in claim 1, wherein the operating loop and idling loop have a parallel arrangement with each other.

25. The circulation system as recited in claim 1, wherein the operating loop and idling loop have a series arrangement with each other.

26. A method of controlling a paint circulation system comprising,
providing an operating loop and at least one idling loop with paint circulating in each loop;
measuring a first set of parameters associated with the paint in the operating loop;
instructing a pump and a first regulator located in the operating loop to maintain the first set of parameters within a predetermined range; and
instructing the pump and a second regulator located in the idling loop to maintain a second set of parameters for the paint circulating in the idling loop.
